(19) United States
(12) Patent Application Publication
(10) Pub. No.: US 2005/0121733 A1
(43) Pub. Date: Jun. 9, 2005

(54) Method of forming a semiconductor device with a high dielectric constant material and an offset spacer

(75) Inventors: Fang-Cheng Chen, Hsin-Chu (TW); Ming-Hung Tsai, Taipei (TW); Hun-Jer Lin, Hsin-Chu City (TW); Yung-Hung Chiu, Taipei (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co.

(21) Appl. No.: 10/731,346

(22) Filed: Dec. 9, 2003

(51) Int. Cl. H01L 21/336; H01L 29/94; H01L 31/062

(52) U.S. Cl. 257/408; 438/303; 438/305; 257/411

(57) ABSTRACT

A process sequence for forming a MOSFET device featuring a high k gate insulator layer, wherein the use of the high k gate insulator layer requires no additional photolithographic procedures, has been developed. After deposition of a high k gate insulator layer followed by the definition of an overlying conductive gate structure, an insulator layer is deposited. An anisotropic dry etch procedure is then employed to first define offset insulator spacers on the sides of the conductive gate structure, then to selectively remove the unwanted portions of the high k gate insulator layer. The use of the high k gate insulator layer provides a thin gate insulator layer with less risk of leakage when compared to counterpart gate insulator layers such as silicon dioxide, while the integration of the definition of the offset insulator spacer step and of the high k gate layer removal procedure, results in fabrication cost savings.

### BACKGROUND OF THE INVENTION

(1) Field of the Invention

The present invention relates to methods used to fabricate semiconductor devices, and more specifically to a method of forming a semiconductor device featuring a high dielectric constant (high k) gate insulator layer and an offset sidewall spacer.

(2) Description of Prior Art

The quest to continually improve semiconductor device performance has emphasized the use of sub-0.25 um features for metal oxide semiconductor field effect transistor (MOSFET) devices. In addition to further improve MOSFET performance and to reduce operating voltage, the thickness of the MOSFET gate insulator layer has continually been reduced. The reduction in thickness for gate insulator layers such as silicon dioxide, can however result in higher unwanted leakage currents when compared to thicker gate insulator counterparts. Therefore to maintain a thin gate insulator layer with reduced risk of leakage high k layers can be used in place of the lower k, silicon dioxide layers. If the high k layer is used as a gate insulator layer the portion of the high k layer not underlying a conductive gate structure has to be removed prior to source/drain formation, requiring an additional and costly process step not needed when silicon dioxide is used as a gate insulator layer.

The present invention will describe a MOSFET device fabrication procedure in which a high k layer is used as a gate insulator layer, however without requiring an additional process step needed to remove unwanted portions of the high k layer. The present invention will feature a specific process procedure in which the removal of unwanted portions of the high k gate insulator layer is integrated with another definition procedure thus minimizing process cost and complexity. Prior art such as Gardner et al in U.S. Pat. No. 6,258,675 B!, as well as Gardner et al in U.S. Pat. No. 5,904,517, describe the use of high k materials for use as sidewall spacers as well as for a component of a composite gate insulator layer. However none of the above prior art disclose the novel process sequence described in the present invention in which the procedure to remove unwanted portions of a high k gate insulator layer is performed simultaneously with another MOSFET device fabrication process step.

### SUMMARY OF THE INVENTION

It is an object of this invention to fabricate a MOSFET device employing a high k layer as the gate insulator layer.

It is another object of this invention to minimize fabrication steps by integrating the removal of unwanted portions of the high k gate insulator layer with another MOSFET device fabrication process step.

It is still another object of this invention to employ a single dry etch procedure to define an insulator offset spacer on the sides of a conductive gate structure followed by selective removal of unwanted portions of the high k gate insulator layer.

In accordance with the present invention a method of fabricating a MOSFET device wherein the definition of an insulator offset spacer located on the sides of a conductive gate structure, and the removal of unwanted portions of a high k gate insulator layer, both accomplished via a single dry etch procedure, is described. A high k layer is deposited on the top surface of a semiconductor substrate. A conductive gate structure is next defined on a first portion of the top surface of the high k layer, with second portions of the high k gate insulator layer remain on an area of the top surface of the semiconductor substrate not covered by the conductive gate structure. An insulator layer is next deposited followed by a selective dry etch procedure which initially defines an offset spacer on the sides of the conductive gate structure, followed by selective removal of exposed portions of the high k layer. A lightly doped source/drain (LDD) region is formed in an area of the semiconductor substrate not covered by the conductive gate structure or by the offset spacer. Another insulator sidewall spacer is defined on the sides of the conductive gate structure followed by formation of a heavily doped source/drain region in an area of the semiconductor substrate not covered by the conductive gate structure, the offset spacer, or the insulator sidewall spacer.

### BRIEF DESCRIPTION OF THE DRAWINGS

The object and other advantages of this invention are best described in the preferred embodiments with reference to the attached drawings that include:

FIGS. 1-6, which schematically, in cross-sectional style, describe key stages used to fabricate a MOSFET device wherein the definition of an insulator offset spacer located on the sides of a conductive gate structure, and the removal of unwanted portions of a high k gate insulator layer, are both accomplished via a single dry etch procedure.

### DESCRIPTION OF THE PREFERRED EMBODIMENTS

The method of fabricating a MOSFET device wherein the definition of an insulator offset spacer located on the sides of a conductive gate structure, and the removal of unwanted portions of a high k gate insulator layer, both accomplished via a single dry etch procedure, will now be described in detail. Semiconductor substrate 1, comprised of P type single crystalline silicon featuring a <100> crystallographic orientation, is used and schematically shown in FIG. 1. Isolation regions, not shown in the drawings, are formed in top portions of non-device regions of semiconductor substrate 1. Isolation regions can be either thermally oxidized field oxide (FOX) regions, or insulator filled shallow trench isolation (STI) regions. Attempts to maximize device performance can be directed to numerous components of a device. For example MOSFET device performance can be increased with decreasing gate insulator thickness. However gate insulator layers comprised of silicon dioxide with a dielectric constant of about 3.9, can present leakage problems when used with thicknesses of less than 10 Angstroms. The ability to use a material for the gate insulator layer comprised with a dielectric constant greater than that of silicon dioxide allows the use of thinner gate insulator layers with less risk of leakage when compared to silicon dioxide counterparts of the same thickness. Therefore to reduce the risk of leakage a thin dielectric layer with a high dielectric constant will be used for the gate insulator layer. Insulator layer 2, comprised with a high dielectric constant (high k) is next formed on semiconductor substrate 1. High k layer 2, can be comprised of silicon nitride, tantalum oxide, silicon oxynitride, zirconium oxide, hafnium oxide, aluminum oxide, and silicon oxide, featuring a dielectric constant greater than 4. High k layer 2, shown schematically in FIG. 1, is formed at a thickness between about 10 to 200 Angstroms, via chemical vapor deposition (CVD) procedures.

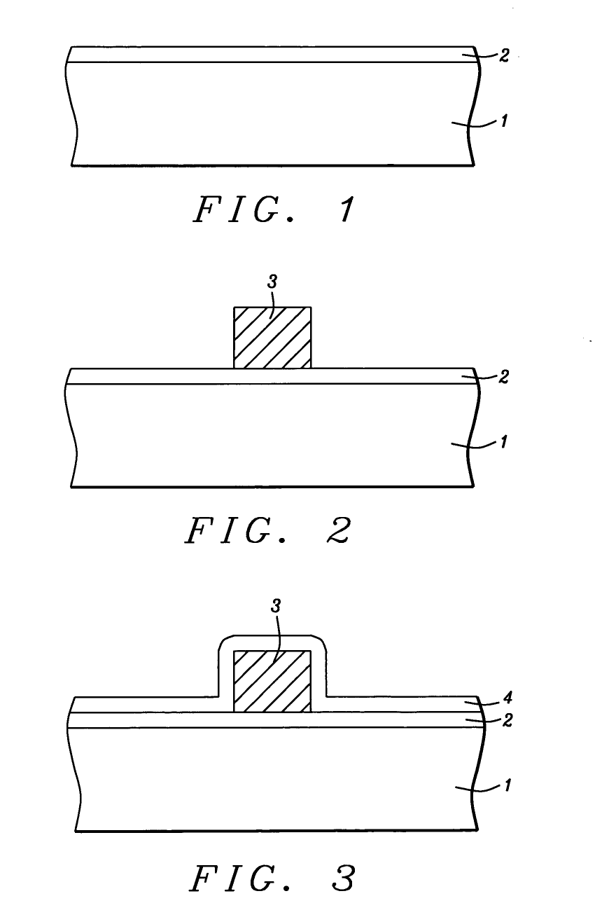

A conductive layer, such as a doped polysilicon layer, is next deposited via low pressure chemical vapor deposition (LPCVD) procedures at a thickness between about 300 to 3000 Angstroms. The polysilicon layer can be in situ doped during deposition via the addition of arsine or phosphine to a silane ambient, or the polysilicon layer can be deposited intrinsically than doped via implantation of arsenic or phosphorous ions. A photoresist shape, not shown in the drawings, is then formed and used as a mask to allow an anisotropic reactive ion etching (RIE) procedure to selectively define conductive gate structure 3, schematically shown in FIG. 2. The RIE procedure is performed using Cl₂ or SF₆ as a selective etchant for polysilicon, with the procedure terminating at the appearance of high k layer 2. If higher word line resistance is desired conductive gate structure 3 can be comprised of a metal silicide layer such as tungsten silicide, or can be comprised of a polycide layer featuring metal silicide on underlying polysilicon. The photoresist shape used for definition of conductive gate structure 3, is removed via plasma oxygen ashing.

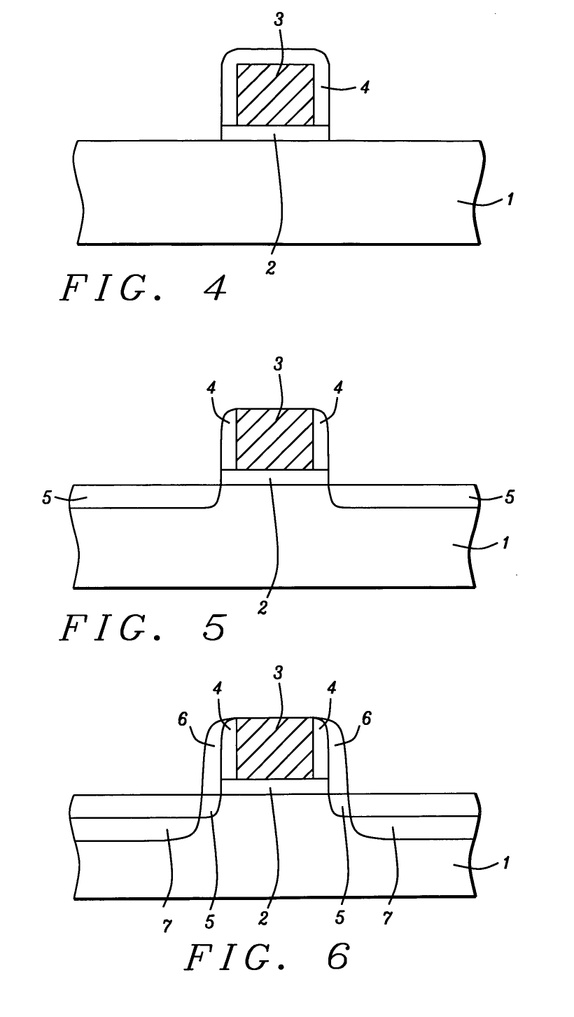

Although the use of high k layer 2, as a gate insulator layer improves MOSFET performance, the additional process step needed to remove exposed portions of high k layer 2, unfortunately increase MOSFET fabrication costs. Therefore a process sequence has been developed in which definition of an offset insulator spacer and removal of the exposed portions of high k layer 2 are integrated, thus avoiding the costly process step needed to only remove exposed portions of high k layer 2. Insulator layer 4, a layer such as silicon oxide or silicon nitride is deposited at a thickness between about 30 to 500 Angstroms, via LPCVD or plasma enhanced chemical vapor deposition (PECVD) procedures. This is schematically shown in FIG. 3. An anisotropic RIE procedure using Ar/CF₄ as an etchant is employed to define offset insulator spacer 4, on the sides of conductive gate structure 2, with the RIE procedure continuing to selectively remove exposed portions of high k layer 2, the portions of high k layer 2, not covered by conductive gate structure 3, or by offset insulator spacers 4. The RIE procedure employing Ar/CF₄ as the etchant is selective, terminating at the appearance of the top surface of conductive gate structure 3, after definition of offset insulator spacers 4, then terminating at the appearance of semiconductor substrate 1, after removal of unwanted portions of high k layer 2. The selectivity of this procedure reduces the risk of silicon damage which can occur with less selective RIE procedures during removal of unwanted portions of high k layer 2. The result of this procedure is schematically shown in FIG. 4.

The completion of the MOSFET device, wherein the definition of an offset spacer on the sides of a conductive gate and removal of unwanted portions of a high k gate insulator layer were simultaneously achieved, is next addressed and schematically described in FIGS. 5-6. Lightly doped source/drain (LDD) region 5, shown schematically in FIG. 5, is formed in portions of semiconductor substrate 1, not covered by conductive gate structure 3, or by offset insulator spacers 4. This is accomplished via implantation of arsenic or phosphorous ions, at an energy between about 2 to 20 KeV, at a dose between about 1E14 to 1E16 atoms/cm². Insulator layer 6, comprised of silicon oxide or silicon nitride, is next deposited at a thickness between about 200 to 1200 Angstroms, via LPCVD or PECVD procedures. An anisotropic RIE procedure, performed using CHF₃ or CF₄ as an etchant, is used to selectively define insulator spacers 6, on the sides of offset spacers 4. Heavily doped source/drain region 7, schematically shown in FIG. 6, is next formed in portions of semiconductor substrate 1, not covered by conductive gate structure 2, by offset insulator spacers 4, or by insulator spacers 6. This is accomplished via implantation of arsenic or phosphorous ions, at an energy between about 15 to 60 KeV, at a dose between about 1E15 to 1E17 atoms/cm². Although this process has been applied to fabrication of an N channel MOSFET device, it can also be applied to fabrication of a P channel MOSFET device, wherein P type source/drain regions would be formed in an N well region located in a top portion of semiconductor substrate 1.

While this invention has been particularly shown and described with reference to the preferred embodiments thereof, it will be understood by those skilled in the art that various changes in form and details may be made without departing from the spirit and scope of this invention.

1. A method of forming a semiconductor device on a semiconductor substrate, comprising the steps of
forming a gate dielectric layer on said semiconductor substrate;
forming a conductive gate structure on a first area of said gate dielectric layer;
forming first insulator spacers on the sides of said conductive gate structure with the procedure used to form said first insulator spacers also removing a second area of said gate dielectric layer, wherein said second area of said gate dielectric layer is not covered by said conductive gate structure or by said first insulator spacers;
forming a first doped region in an area of said semiconductor substrate not covered by said conductive gate structure of by said first insulator spacers;
forming second insulator spacers on the sides of said first insulator spacers; and forming a second doped region in an area of said semiconductor substrate not covered by said conductive gate structure, not covered by said first insulator spacers, and not covered by said second insulator spacers.

2. The method of claim 1, wherein said gate dielectric layer is comprised of a layer selected from the group consisting of silicon nitride, tantalum oxide, silicon oxynitride, hafnium oxide, zirconium oxide, aluminum oxide and silicon oxide.

3. The method of claim 1, wherein the thickness of said gate dielectric layer is between about 10 to 200 Angstroms.

4. The method of claim 1, wherein the dielectric constant of said gate dielectric layer is greater than 4.

5. The method of claim 1, wherein said conductive gate structure is comprised of doped polysilicon, at a thickness between about 300 to 3000 Angstroms.

6. The method of claim 1, wherein said conductive gate structure is comprised of metal silicide such as tungsten silicide.

7. The method of claim 1, wherein said first insulator spacers are comprised of silicon oxide, at a thickness between about 10 to 300 Angstroms.

8. The method of claim 1, wherein said first insulator spacers are comprised of silicon nitride, at a thickness between about 30 to 400 Angstroms.

9. The method of claim 1, wherein procedure used to define said first insulator spacers on sides of said conductive gate structure, and to remove exposed portions of said gate dielectric layer, is an anisotropic RIE procedure performed using Ar/CF₄ as a selective etchant for said first insulator spacer and for said gate dielectric layer.

10. A method of forming a semiconductor device on a semiconductor substrate featuring a high dielectric constant (high k), gate insulator layer, comprising the steps of:
forming said high k gate insulator layer on said semiconductor substrate;
forming a conductive gate structure overlying a first area of said high k gate insulator layer;
depositing an insulator layer;
performing a dry etch procedure to first define first insulator spacers on the sides of said conductive gate structure via etching of said insulator layer, and then to remove exposed portions of said high gate dielectric layer, wherein said exposed portions of said high k gate insulator layer are portions not covered by said conductive gate structure or by said first insulator spacers;
forming a lightly doped source/drain region in an area of said semiconductor substrate not covered by said conductive gate structure of by said first insulator spacers;
forming second insulator spacers on the sides of said first insulator spacers; and
forming a heavily doped source/drain region in an area of said semiconductor substrate not covered by said conductive gate structure, not covered by said first insulator spacers, and not covered by said second insulator spacers.

11. The method of claim 10, wherein said high k gate insulator layer is layer selected from the group consisting of silicon nitride, tantalum oxide, silicon oxynitride, zirconium oxide, hafnium oxide, aluminum oxide, and silicon oxide.

12. The method of claim 10, wherein the thickness of said high k gate insulator layer is between about 10 to 200 Angstroms.

13. The method of claim 10, wherein the dielectric constant of said high k gate insulator layer is greater than 4.

14. The method of claim 10, wherein said conductive gate structure is comprised of doped polysilicon, at a thickness between about 300 to 3000 Angstroms.

15. The method of claim 10, wherein said conductive gate structure is comprised of tungsten silicide.

16. The method of claim 10, wherein said insulator layer is selected from the group consisting of silicon oxide, silicon nitride, or silicon oxynitride.

17. The method of claim 10, wherein the thickness of said insulator layer is between about 30 to 500 Angstroms.

18. The method of claim 10, wherein procedure used to both define said first insulator spacers on sides of said conductive gate structure, and to remove exposed portions of said high k gate insulator layer, is an anisotropic RIE procedure performed using Ar/CF₄ as a selective etchant for said insulator layer and for said high k gate insulator

19. A MOSFET device structure comprising:
a high dielectric constant (high k) gate insulator layer on a portion of a top surface of a semiconductor substrate;
a conductive gate structure on a first portion of said high k gate insulator layer;
first insulator spacers on sides of said conductive gate structure and overlying second portions of said high k gate insulator layer;
second insulator spacers on sides of said first insulator spacers and on sides of said second portions of said high k gate insulator layer;
a first doped region in a portion of said semiconductor substrate not covered by said conductive gate structure or by second portions of said high k gate insulator layer; and
a second doped region in a portion of said semiconductor substrate not covered by said conductive gate structure, by said second portions of said high k gate insulator layer, and by said second insulator spacers.

20. The MOSFET device structure of claim 19, wherein said high k gate insulator layer is selected from a group consisting of silicon nitride, tantalum oxide, silicon oxynitride, zirconium oxide, hafnium oxide, aluminum oxide, and silicon oxide.

21. The MOSFET device structure of claim 19, wherein the thickness of said high k gate insulator layer is between about 10 to 200 Angstroms.

22. The MOSFET device structure of claim 19, wherein the dielectric constant of said high k gate insulator layer is greater than 4.

23. The MOSFET device structure of claim 19, wherein said conductive gate structure is comprised of doped polysilicon or tungsten silicide, at a thickness between about 300 to 3000 Angstroms.

24. The MOSFET device structure of claim 19, wherein said first insulator spacers are selected from the group consisting of silicon oxide, silicon nitride, or silicon oxynitride.

25. The MOSFET device structure of claim 19, wherein the thickness of said first insulator spacers is between about 30 to 500 Angstroms.

26. The MOSFET device structure of claim 19, wherein said second insulator spacers are comprised of silicon oxide or silicon nitride, at a thickness between about 200 to 1200 Angstroms.

27. The MOSFET device structure of claim 19, wherein said first doped region is a lightly doped source/drain region.

28. The MOSFET device structure of claim 19, wherein said second doped region is a heavily doped source/drain region.
